(19) United States
(12) Patent Application Publication
(10) Pub. No.: US 2021/0189176 A1
(43) Pub. Date: Jun. 24, 2021

(54) POLISHING SOLUTION, POLISHING SOLUTION SET, AND POLISHING METHOD

(71) Applicant: HITACHI CHEMICAL COMPANY, LTD., Tokyo (JP)

(72) Inventors: Mamiko KANAMARU, Chiyoda-ku, Tokyo (JP); Nao YAMAMURA, Chiyoda-ku, Tokyo (JP)

(21) Appl. No.: 16/650,691

(22) PCT Filed: Sep. 29, 2017
(86) PCT No.: PCT/JP2017/035588

§ 371 Date: Mar. 25, 2020

(51) Int. Cl. C09G 1/02; C08F 212/08; C08F 220/06; C08F 222/02

(52) U.S. Cl. CPC C09G 1/02; C08F 222/02; C08F 220/06; C08F 212/08

(57) ABSTRACT

A polishing liquid containing abrasive grains, a copolymer, and a liquid medium, in which the copolymer has a structure unit derived from at least one styrene compound selected from the group consisting of styrene and a styrene derivative and a structure unit derived from at least one selected from the group consisting of acrylic acid and maleic acid, and a ratio of the structure unit derived from the styrene compound in the copolymer is 15 mol % or more.

### TECHNICAL FIELD

The present invention relates to a polishing liquid, a polishing liquid set, and a polishing method. In particular, the present invention relates to a polishing liquid, a polishing liquid set, and a polishing method which is used in a flattening step of a base substrate surface that is a manufacturing technique for a semiconductor element. More specifically, the present invention relates to a polishing liquid, a polishing liquid set, and a polishing method which is used in a flattening step of an insulating film for Shallow Trench Isolation (shallow trench isolation: STI), a pre-metal insulating film, an interlayer insulating film, or the like.

### BACKGROUND ART

In recent years, processing techniques for increasing density and miniaturization are becoming ever more important in manufacturing steps for semiconductor elements. CMP (Chemical Mechanical Polishing) technique that is one of processing techniques has become an essential technique in manufacturing steps for semiconductor elements, for STI formation, flattening of pre-metal insulating films or interlayer insulating films, formation of plugs or embedded metal wirings, or the like.

In a CMP step or the like for formation of STI, polishing of a laminate, which has a stopper (a polishing stop layer containing a stopper material) disposed on the convex portion of a substrate having a concavo-convex pattern and an insulating member (for example, an insulating film such as a silicon oxide film) disposed on the substrate and the stopper so as to fill the concave portion of the concavo-convex pattern, is performed. In such polishing, polishing of the insulating member is stopped by the stopper. That is, polishing of the insulating member is stopped when the stopper is exposed. The reason for this is that the amount of the insulating material polished (the amount of the insulating material removed) contained in the insulating member is difficult to artificially control, and thus the insulating member is polished until the stopper is exposed, thereby controlling the degree of polishing. In this case, the polishing selectivity of the insulating material with respect to the stopper material (polishing rate ratio: a polishing rate for the insulating material/a polishing rate for the stopper material) is required to be increased.

For this problem, Patent Literature 1 described below discloses that the polishing selectivity of silicon oxide with respect to polysilicon is improved by using a copolymer of styrene and acrylonitrile. Patent Literature 2 described below discloses that the polishing selectivity of the insulating material with respect to silicon nitride is improved by using a polishing liquid containing ceria particles, a dispersant, a specific water-soluble polymer, and water. Patent Literature 3 described below discloses that the polishing selectivity of the insulating material with respect to polysilicon is improved by using a polishing liquid containing abrasive grains, a polysilicon polishing inhibitor, and water as a polishing liquid for polishing a silicon oxide film on polysilicon.

### CITATION LIST

### Patent Literature

Patent Literature 1: International Publication WO 2015/170436

Patent Literature 2: Japanese Unexamined Patent Publication No. 2011-103498

Patent Literature 3: International Publication WO 2007/055278

### SUMMARY OF INVENTION

### Technical Problem

In semiconductor devices in recent years, miniaturization has been further accelerated, and thinning has progressed along with the reduction in wiring width. Along with this, in the CMP step or the like for formation of STI, it is necessary to polish the insulating member while suppressing excessive polishing of the stopper disposed on the convex portion of the substrate having a concavo-convex pattern. From such a viewpoint, it is required for the polishing liquid to further improve the polishing selectivity of the insulating material with respect to the stopper material.

The present invention is to solve the above-described problems, and an object thereof is to provide a polishing liquid, a polishing liquid set, and a polishing method which can improve polishing selectivity of an insulating material with respect to a stopper material.

### Solution to Problem

The present inventor has conducted various studies in order to solve the above problems, and as a result, found that the polishing selectivity of the insulating material with respect to the stopper material can be improved by using a specific copolymer which has a structure unit derived from at least one styrene compound selected from the group consisting of styrene and a styrene derivative and a structure unit derived from at least one selected from the group consisting of acrylic acid and maleic acid.

A polishing liquid of the present invention contains abrasive grains, a copolymer, and a liquid medium, in which the copolymer has a structure unit derived from at least one styrene compound selected from the group consisting of styrene and a styrene derivative and a structure unit derived from at least one selected from the group consisting of acrylic acid and maleic acid, and a ratio of the structure unit derived from the styrene compound in the copolymer is 15 mol % or more.

According to the polishing liquid of the present invention, the polishing selectivity of the insulating material with respect to the stopper material can be improved.

Incidentally, in a conventional polishing liquid, although high polishing selectivity of the insulating material with respect to the stopper material is obtainable in evaluation of blanket wafers (unpatterned wafers), in evaluation of pattern wafers (wafers having a pattern; for example, a laminate which has a stopper disposed on the convex portion of a substrate having a concavo-convex pattern and an insulating member disposed on the substrate and the stopper so as to fill the concave portion of the concavo-convex pattern), since the polishing selectivity of the insulating material with respect to the stopper material is high, polishing of the stopper on the convex portion may be suppressed, but the insulating member in the concave portion may be excessively polished, so that a remaining step height called dishing may increase and flatness may deteriorate. On the other hand, according to the polishing liquid of the present invention, in polishing of the insulating member using the stopper, excessive polishing of the stopper on the convex portion and excessive polishing of the insulating member in the concave portion are sufficiently suppressed (the loss amount due to excessive polishing is suppressed), and thus high flatness can be obtained. Furthermore, according to the polishing liquid of the present invention, a base substrate having a concavo-convex pattern can be polished with satisfactory flatness without dependence on the pattern density (for example, without dependence on “a line (L) as a convex portion/a space (S) as a concave portion”).

A zeta potential of the abrasive grains is preferably negative.

The ratio of the structure unit derived from the styrene compound is preferably 15 to 60 mol %.

The copolymer preferably has a structure unit derived from styrene. The copolymer preferably has a structure unit derived from acrylic acid. The copolymer preferably has a structure unit derived from maleic acid.

A degree of solubility of the styrene compound with respect to water at 25° C. is preferably 0.1 g/100 ml or less.

A weight average molecular weight of the copolymer is preferably 20000 or less.

A content of the copolymer is preferably 0.05 to 2.0% by mass.

The abrasive grains preferably contain at least one selected from the group consisting of ceria, silica, alumina, zirconia, and yttria. The abrasive grains preferably contain cerium oxycarbonate-derived ceria.

The polishing liquid of the present invention preferably further contains at least one selected from the group consisting of a phosphate and a polymer having a structure unit derived from acrylic acid.

The polishing liquid of the present invention is preferably used for polishing a surface to be polished containing silicon oxide.

A polishing liquid set of the present invention contains constituent components of the above-described polishing liquid stored while being divided into a first liquid and a second liquid, the first liquid containing the abrasive grains and a liquid medium, the second liquid containing the copolymer and a liquid medium.

A first embodiment of a polishing method of the present invention includes a step of polishing a surface to be polished by using the above-described polishing liquid or a polishing liquid obtained by mixing the first liquid and the second liquid of the above-described polishing liquid set.

A second embodiment of a polishing method of the present invention is a polishing method for a surface to be polished containing an insulating material and silicon nitride, the polishing method including a step of selectively polishing the insulating material with respect to the silicon nitride by using the above-described polishing liquid or a polishing liquid obtained by mixing the first liquid and the second liquid of the above-described polishing liquid set.

A third embodiment of a polishing method of the present invention is a polishing method for a surface to be polished containing an insulating material and polysilicon, the polishing method including a step of selectively polishing the insulating material with respect to the polysilicon by using the above-described polishing liquid or a polishing liquid obtained by mixing the first liquid and the second liquid of the above-described polishing liquid set.

### Advantageous Effects of Invention

According to the present invention, the polishing selectivity of the insulating material with respect to the stopper material can be improved. Furthermore, according to the present invention, in polishing of the insulating member using the stopper, excessive polishing of the stopper on the convex portion and excessive polishing of the insulating member in the concave portion are sufficiently suppressed (the loss amount due to excessive polishing is suppressed), and thus high flatness can be obtained. Furthermore, according to the present invention, the base substrate having a concavo-convex pattern can be polished with satisfactory flatness without dependence on the pattern density (for example, without dependence on L/S).

According to the present invention, even in the case of using any of silicon nitride and polysilicon as the stopper material, polishing on the stopper can be sufficiently stopped. In particular, in the case of using silicon nitride as the stopper material, the polishing rate for silicon nitride can be sufficiently suppressed. According to the present invention, in polishing of the insulating material by using silicon nitride as the stopper material, when the stopper is exposed, it is possible to suppress that the stopper and the insulating member filled in the concave portion are excessively polished.

According to the present invention, in the CMP technique of flattening an STI insulating film, a pre-metal insulating film, an interlayer insulating film, or the like, these insulating films can also be highly flattened without dependence on the pattern density.

According to the present invention, it is possible to provide use of a polishing liquid or a polishing liquid set in a flattening step of a base substrate surface. According to the present invention, it is possible to provide use of a polishing liquid or a polishing liquid set in a flattening step of STI insulating films, pre-metal insulating films, or interlayer insulating films. According to the present invention, it is possible to provide use of a polishing liquid or a polishing liquid set in a polishing step of selectively polishing an insulating material with respect to a stopper material.

### BRIEF DESCRIPTION OF DRAWINGS

FIG. 1 is a schematic cross-sectional view illustrating a pattern wafer used in Examples.

### DESCRIPTION OF EMBODIMENTS

Hereinafter, an embodiment of the present invention will be described in detail.

<Definition>

In the present specification, the term “polishing liquid” is defined as a composition to be brought into contact with a surface to be polished, at the time of polishing. The term “polishing liquid” itself does not limit any components contained in the polishing liquid. As described later, the polishing liquid of the present embodiment contains abrasive grains. The abrasive grains are also referred to as “abrasive particles,” but are referred to as “abrasive grains” in the present specification. The abrasive grains are generally solid particles, and it is considered that an object to be removed is removed by the mechanical action of the abrasive grains and the chemical action of the abrasive grains (mainly, the surface of the abrasive grains) at the time of polishing, but the polishing mechanism is not limited thereto.

In the present specification, the term “step” includes not only an independent step but also a step by which an intended action of the step is achieved, even though the step cannot be clearly distinguished from other steps. A numerical range that has been indicated by use of “to” indicates the range that includes the numerical values which are described before and after “to”, as the minimum value and the maximum value, respectively. In the numerical ranges that are described stepwise in the present specification, the upper limit value or the lower limit value of the numerical range of a certain stage can be arbitrarily combined with the upper limit value or the lower limit value of the numerical range of another stage. In the numerical ranges that are described in the present specification, the upper limit value or the lower limit value of the numerical value range may be replaced with the value shown in the examples. Materials listed as examples in the present specification may be used singly or in combinations of two or more, unless otherwise specifically indicated. When a plurality of substances corresponding to each component exist in the composition, the content of each component in the composition means the total amount of the plurality of substances that exist in the composition, unless otherwise specified. “Polishing Rate” means a rate at which a material is removed per unit time (Removal Rate). “A or B” may include either one of A and B, and may also include both of A and B. “A or more” in the numerical range means A and a range of more than A. “A or less” in the numerical range means A and a range of less than A.

<Polishing Liquid>

The polishing liquid of the present embodiment contains abrasive grains, an additive, and a liquid medium. The term “additive” refers to a substance contained in the polishing liquid in addition to the abrasive grains and the liquid medium, for adjusting polishing characteristics such as polishing rate and polishing selectivity; polishing liquid characteristics such as dispersibility of the abrasive grains and storage stability, and the like. The polishing liquid of the present embodiment can be used as a polishing liquid for CMP. Hereinafter, essential components and optional components of the polishing liquid will be described.

The abrasive grains preferably contain at least one selected from the group consisting of ceria (cerium oxide), silica (silicon oxide), alumina, zirconia, and yttria and more preferably contain ceria, from the viewpoint of easily obtaining a desired polishing rate for the insulating material. The abrasive grains may be used singly or in combination of two or more kinds thereof. The abrasive grains may be composite particles in which other particles adhere to the surface of one particle.

Ceria can be obtained by oxidizing cerium salts such as cerium carbonate, cerium oxycarbonate, cerium nitrate, cerium sulfate, cerium oxalate, and cerium hydroxide. Examples of the oxidation method include a firing method in which a cerium salt is fired at about 600 to 900° C. and a chemical oxidation method in which a cerium salt is oxidized using an oxidizing agent such as hydrogen peroxide. As the ceria, from the viewpoint of further improving the polishing selectivity of the insulating material with respect to the stopper material and flatness, at least one selected from the group consisting of cerium oxycarbonate-derived ceria and cerium carbonate-derived ceria is preferred and cerium oxycarbonate-derived ceria is more preferred.

The lower limit of the average particle diameter of the abrasive grains is preferably 50 nm or more, more preferably 100 nm or more, and even more preferably 120 nm or more, from the viewpoint of further improving the polishing rate for the insulating material. The upper limit of the average particle diameter of the abrasive grains is preferably 300 nm or less, more preferably 250 nm or less, even more preferably 200 nm or less, particularly preferably 180 nm or less, and extremely preferably 150 nm or less, from the viewpoint of suppressing scratches at the polished surface. From these viewpoints, the average particle diameter of the abrasive grains is more preferably 50 to 300 nm.

The “average particle diameter” of the abrasive grains is an average particle diameter (D50) of the abrasive grains in the polishing liquid or in the slurry of a polishing liquid set described later and means an average secondary particle diameter of the abrasive grains. The average particle diameter of the abrasive grains can be measured, for example, for the polishing liquid or the slurry of a polishing liquid set described later, for example, using a laser diffraction scattering type particle size distribution measuring apparatus (trade name: Microtrac MT3300EXII manufactured by MicrotracBEL Corp.).

The zeta potential of the abrasive grains in the polishing liquid is preferably in the following range. The zeta potential of the abrasive grains is preferably negative (less than 0 mv) from the viewpoint of further improving flatness. That is, the polishing liquid of the present embodiment preferably contains anionic abrasive grains. By using the abrasive grains having a negative zeta potential, it is easy to suppress aggregation between the abrasive grains and an anionic polymer (for example, a polymer having a carboxyl group derived from acrylic acid or maleic acid). The upper limit of the zeta potential of the abrasive grains is more preferably −5 mV or less, even more preferably −10 mV or less, particularly preferably −20 mV or less, extremely preferably −30 mV or less, highly preferably −40 mV or less, and still even more preferably −50 mV or less, from the viewpoint of further improving flatness and the viewpoint of enhancing the storage stability of the polishing liquid. The lower limit of the zeta potential of the abrasive grains is preferably −80 mV or more, more preferably −70 mV or more, and even more preferably −60 mV or more, from the viewpoint of easily obtaining a desired polishing rate for the insulating material. From these viewpoints, the zeta potential of the abrasive grains is more preferably −80 mV or more and less than 0 mV.

The zeta potential (ζ [mV]) can be measured using a zeta potential measuring device (for example, DelsaNano C (device name) manufactured by Beckman Coulter, Inc.). The zeta potential of the abrasive grains in the polishing liquid can be obtained, for example, by putting the polishing liquid in a dense cell unit (cell for a high-concentration sample) for the zeta potential measuring device and then measuring.

The content of the abrasive grains is preferably in the following range based on the total mass of the polishing liquid. The lower limit of the content of the abrasive grains is preferably 0.05% by mass or more, more preferably 0.1% by mass or more, even more preferably 0.15% by mass or more, particularly preferably 0.2% by mass or more, and extremely preferably 0.25% by mass or more, from the viewpoint of further improving the polishing rate for the insulating material. The upper limit of the content of the abrasive grains is preferably 20% by mass or less, more preferably 15% by mass or less, even more preferably 10% by mass or less, particularly preferably 5.0% by mass or less, extremely preferably 3.0% by mass or less, and highly preferably 1.0% by mass or less, from the viewpoint of enhancing the storage stability of the polishing liquid. From these viewpoints, the content of the abrasive grains is more preferably 0.05 to 20% by mass.

(Additive)

[Copolymer]

The polishing liquid of the present embodiment contains, as an additive, a copolymer (hereinafter, referred to as “copolymer P”) having a structure unit derived from at least one styrene compound selected from the group consisting of styrene and a styrene derivative (hereinafter, referred to as “first structure unit” in some cases) and a structure unit derived from at least one selected from the group consisting of acrylic acid and maleic acid (hereinafter, referred to as “second structure unit” in some cases). The ratio of the structure unit derived from the styrene compound in the copolymer P is 15 mol % or more based on the whole copolymer P, from the viewpoint of improving the polishing selectivity of the insulating material with respect to the stopper material and flatness.

The copolymer P has an effect (an effect as a polishing inhibitor) of suppressing an excessive increase in polishing rate for the stopper material (such as silicon nitride or polysilicon). Furthermore, by using the copolymer P, excessive polishing of the insulating member (such as a silicon oxide film) after the stopper is exposed is suppressed and high flatness can be obtained.

The detailed reason why such an effect is exhibited is not necessarily clear, but the present inventor speculates an example of the reason in the following way. That is, the carboxyl group derived from acrylic acid or maleic acid in the copolymer P acts on a hydrophilic insulating member by hydrogen bonding so that the copolymer P is adsorbed to the insulating member to cover the insulating member. Furthermore, the styrene compound-derived benzene ring in the copolymer P acts on a hydrophobic stopper (for example, relatively hydrophobic silicon nitride having hydrophilicity weaker than that of the insulating material (such as silicon oxide); hydrophobic polysilicon) by a hydrophobic interaction so that the copolymer P is adsorbed to the stopper to cover the stopper. Furthermore, the copolymer P obtained by using these monomers has higher solubility than that of a polymer not using these monomers (for example, a polymer using methacrylic acid instead of acrylic acid or maleic acid) and the aforementioned action is suitably obtainable. According to these, it is speculated that progress of polishing by the abrasive grains is alleviated and the polishing rate can be sufficiently suppressed.

The copolymer P preferably has a structure unit derived from styrene from the viewpoint of further improving the polishing selectivity of the insulating material with respect to the stopper material and flatness. The copolymer P preferably has a structure unit derived from acrylic acid from the viewpoint of further improving the polishing selectivity of the insulating material with respect to the stopper material and flatness. The copolymer P preferably has a structure unit derived from maleic acid from the viewpoint of further improving the polishing selectivity of the insulating material with respect to the stopper material and flatness.

The degree of solubility of the styrene compound with respect to water at 25° C. is preferably in the following range. The upper limit of the degree of solubility of the styrene compound is preferably 0.1 g/100 ml or less, more preferably 0.05 g/100 ml or less, even more preferably 0.03 g/100 ml or less, from the viewpoint of easily exerting the aforementioned hydrophobic interaction sufficiently and further improving the polishing selectivity of the insulating material with respect to the stopper material and flatness. The lower limit of the degree of solubility of the styrene compound is preferably 0.01 g/100 ml or more, more preferably 0.02 g/100 ml or more, and even more preferably 0.025 g/100 ml or more, from the viewpoint of easily maintaining the solubility of the whole copolymer P and further improving the polishing selectivity of the insulating material with respect to the stopper material and flatness. The degree of solubility of styrene with respect to water at 25° C. is 0.03 g/100 ml.

Examples of the styrene derivative include alkyl styrene (such as α-methylstyrene), alkoxy styrene (such as α-methoxystyrene or p-methoxystyrene), m-chlorostyrene, 4-carboxystyrene, and styrenesulfonic acid. As the styrene derivative, a styrene derivative not having a hydrophilic group can be used. Examples of the hydrophilic group include a polyether group, a hydroxyl group, a carboxyl group, a sulfonic acid group, and an amino group. The copolymer P may have a structure unit derived from other monomer which is polymerizable with the styrene compound, acrylic acid, or maleic acid. Examples of such a monomer include methacrylic acid.

The copolymer P may be used singly or in combination of two or more kinds thereof for adjusting polishing characteristics such as polishing selectivity or flatness, and the like. As the two or more kinds of the copolymer P, copolymers having different ratios of structure units derived from the styrene compound can be used in combination.

The ratio of the first structure unit derived from the styrene compound in the copolymer P is 15 mol % or more based on the whole copolymer P and is preferably in the following range. The upper limit of the ratio of the first structure unit is preferably 60 mol % or less, more preferably 50 mol % or less, even more preferably 40 mol % or less, and particularly preferably 35 mol % or less, from the viewpoint of having excellent solubility of the copolymer P and easily improving the polishing selectivity of the insulating material with respect to the stopper material and flatness. The lower limit of the ratio of the first structure unit is preferably 17.5 mol % or more, more preferably 20 mol % or more, even more preferably 22.5 mol % or more, particularly preferably 25 mol % or more, extremely preferably 27.5 mol % or more, and highly preferably 30 mol % or more, from the viewpoint of further improving the polishing selectivity of the insulating material with respect to the stopper material and flatness. From these viewpoints, the ratio of the first structure unit is more preferably 15 to 60 mol %, 17.5 to 60 mol %, 20 to 60 mol %, 22.5 to 60 mol %, 25 to 50 mol %, 27.5 to 50 mol %, 30 to 50 mol %, 30 to 40 mol %, or 30 to 35 mol %.

The ratio of the second structure unit in the copolymer P is preferably in the following range based on the whole copolymer P. The upper limit of the ratio of the second structure unit is preferably 85 mol % or less, more preferably 82.5 mol % or less, even more preferably 80 mol % or less, particularly preferably 77.5 mol % or less, extremely preferably 75 mol % or less, highly preferably 72.5 mol % or less, and still even more preferably 70 mol % or less, from the viewpoint of further improving polishing selectivity and flatness. The lower limit of the ratio of the second structure unit is preferably 40 mol % or more, more preferably 50 mol % or more, even more preferably 60 mol % or more, and particularly preferably 65 mol % or more, from the viewpoint of having excellent solubility of the copolymer P and easily improving the polishing selectivity of the insulating material with respect to the stopper material. From these viewpoints, the ratio of the second structure unit is more preferably 40 to 85 mol %, 40 to 82.5 mol %, 40 to 80 mol %, 40 to 77.5 mol %, 50 to 75 mol %, 50 to 72.5 mol %, 50 to 70 mol %, 60 to 70 mol %, or 65 to 70 mol %.

The upper limit of the weight average molecular weight Mw of the copolymer P is preferably 20000 or less, more preferably less than 20000, even more preferably 19000 or less, particularly preferably 18000 or less, extremely preferably 17000 or less, and highly preferably 16000 or less, from the viewpoint of easily obtaining suitable polishing selectivity and a desired polishing rate for the insulating material. The lower limit of the weight average molecular weight Mw of the copolymer P is preferably 1000 or more, more preferably 3000 or more, even more preferably 5000 or more, and particularly preferably 6000 or more, from the viewpoint of further improving the polishing selectivity of the insulating material with respect to the stopper material and flatness. The lower limit of the weight average molecular weight Mw of the copolymer P may be 8000 or more, 10000 or more, or 12000 or more. From these viewpoints, the weight average molecular weight Mw of the copolymer P is more preferably 1000 to 20000. The weight average molecular weight is a value measured by gel permeation chromatography (GPC) and converted in terms of polyethylene glycol/polyethylene oxide.

Specifically, the weight average molecular weight can be measured by the following method.

### [Measuring Method]

Equipment used (detector): “RID-10A” differential refractometer for liquid chromatograph manufactured by SHIMADZU CORPORATION

Pump: “RID-10A” manufactured by SHIMADZU CORPORATION

Degassing apparatus: “DGU-20A_{3R}” manufactured by SHIMADZU CORPORATION

Data processing: “LC solution” manufactured by SHIMADZU CORPORATION

Column: “Gelpak GL-W530+Gelpak GL-W540” manufactured by Hitachi Chemical Techno Service Co., LTD., inner diameter 10.7 mm×300 mm

Eluent: 50 mM-Na₂HPO₄ aqueous solution/acetonitrile=90/10 (v/v)

Measurement temperature: 40° C.

Flow rate: 1.0 ml/min

Measurement time: 60 minutes

Sample: Sample prepared by adjusting a concentration with a solution having the same composition as the eluent so that the resin concentration becomes 0.2% by mass and filtering through a 0.45 μm membrane filter

Injection amount: 100 μl

Standard substance: Polyethylene glycol/polyethylene oxide manufactured by Tosoh Corporation

The content of the copolymer P is preferably in the following range based on the total mass of the polishing liquid. The lower limit of the content of the copolymer P is preferably 0.05% by mass or more, more preferably 0.07% by mass or more, and even more preferably 0.10% by mass or more, from the viewpoint of further improving the polishing selectivity of the insulating material with respect to the stopper material and flatness. The upper limit of the content of the copolymer P is preferably 2.0% by mass or less, more preferably 1.0% by mass or less, even more preferably 0.8% by mass or less, particularly preferably 0.5% by mass or less, extremely preferably 0.4% by mass or less, and highly preferably 0.3% by mass or less, from the viewpoint of easily obtaining a desired polishing rate for the insulating material. From these viewpoints, the content of the copolymer P is more preferably 0.05 to 2.0% by mass and even more preferably 0.05 to 1.0% by mass. In the case of using a plurality of copolymers as the copolymer P, the total content of the respective copolymers preferably satisfies the above range.

[Dispersant]

The polishing liquid of the present embodiment can contain a dispersant (a dispersant of the abrasive grains; excluding a compound corresponding to the copolymer P) as necessary. Examples of the dispersant include a phosphate compound; a hydrogen phosphate compound; a homopolymer of unsaturated carboxylic acid such as acrylic acid, methacrylic acid, maleic acid, fumaric acid, or itaconic acid (such as polyacrylic acid); an ammonium salt or amine salt of this polymer; a copolymer of an unsaturated carboxylic acid such as acrylic acid, methacrylic acid, maleic acid, fumaric acid, or itaconic acid and a monomer such as alkyl acrylate (such as methyl acrylate or ethyl acrylate), hydroxyalkyl acrylate (such as hydroxyethyl acrylate), alkyl methacrylate (such as methyl methacrylate or ethyl methacrylate), hydroxyalkyl methacrylate (such as hydroxyethyl methacrylate), vinyl acetate, or vinyl alcohol (such as a copolymer of acrylic acid or alkyl acrylate); and an ammonium salt or amine salt of this copolymer. The dispersant may be used singly or in combination of two or more kinds thereof.

As the phosphate compound, at least one selected from the group consisting of a phosphate and a derivative thereof (a phosphate derivative) can be used. As the hydrogen phosphate compound, at least one selected from the group consisting of a hydrogen phosphate and a derivative thereof (a hydrogen phosphate derivative) can be used.

Examples of the phosphate include potassium phosphate, sodium phosphate, ammonium phosphate, and calcium phosphate, and specific examples thereof include tripotassium phosphate, trisodium phosphate, ammonium phosphate, and tricalcium phosphate. Examples of the phosphate derivative include sodium diphosphate, potassium diphosphate, potassium polyphosphate, ammonium polyphosphate, and calcium polyphosphate.

Examples of the hydrogen phosphate include potassium hydrogen phosphate, sodium hydrogen phosphate, ammonium hydrogen phosphate, and calcium hydrogen phosphate, and specific examples thereof include dipotassium hydrogen phosphate, disodium hydrogen phosphate, diammonium hydrogen phosphate, calcium hydrogen phosphate, potassium dihydrogen phosphate, sodium dihydrogen phosphate, ammonium dihydrogen phosphate, and calcium dihydrogen phosphate. Examples of the hydrogen phosphate derivative include potassium tetradodecyl hydrogen phosphate, sodium dodecyl hydrogen phosphate, and dodecylammonium hydrogen phosphate.

The polishing liquid of the present embodiment preferably contains at least one selected from the group consisting of a phosphate (such as ammonium dihydrogen phosphate) and a polymer having a structure unit derived from acrylic acid (such as a copolymer of acrylic acid and alkyl acrylate) from the viewpoint of easily obtaining a desired polishing rate for the insulating material.

In the case in which the dispersant is the aforementioned various polymers, the weight average molecular weight of the dispersant is preferably 5000 to 15000. When the weight average molecular weight of the dispersant is 5000 or more, repulsion between the abrasive grains easily occurs by steric hindrance of the dispersant adsorbed to the abrasive grains and dispersion stability is easily improved. When the weight average molecular weight of the dispersant is 15000 or less, it is easy to prevent the dispersants adsorbed to the abrasive grains from being crosslinked and aggregated. The weight average molecular weight of the dispersant can be measured in the same manner as in the weight average molecular weight of the copolymer P.

The content of the dispersant is preferably in the following range based on the total mass of the polishing liquid. The lower limit of the content of the dispersant is preferably 0.0005% by mass or more, more preferably 0.001% by mass or more, even more preferably 0.002% by mass or more, particularly preferably 0.003% by mass or more, highly preferably 0.004% by mass or more, and extremely preferably 0.005% by mass or more, from the viewpoint of easily dispersing the abrasive grains suitably. The upper limit of the content of the dispersant is preferably 0.05% by mass or less, more preferably 0.04% by mass or less, even more preferably 0.03% by mass or less, particularly preferably 0.02% by mass or less, and extremely preferably 0.01% by mass or less, from the viewpoint of easily preventing the aggregation of the abrasive grains dispersed once. From these viewpoints, the content of the dispersant is more preferably 0.0005 to 0.05% by mass.

[pH Adjusting Agent]

The polishing liquid of the present embodiment can contain a pH adjusting agent (excluding a compound corresponding to the copolymer P or the dispersant). The pH can be adjusted to a desired pH by the pH adjusting agent.

The pH adjusting agent is not particularly limited, and examples thereof include an organic acid, an inorganic acid, an organic base, and an inorganic base. Examples of the organic acid include formic acid, acetic acid, propionic acid, butyric acid, valeric acid, caproic acid, lactic acid, maleic acid, phthalic acid, citric acid, and succinic acid. Examples of the inorganic acid include nitric acid, sulfuric acid, hydrochloric acid, phosphoric acid, and boric acid. Examples of the organic base include triethylamine, pyridine, piperidine, pyrrolidine, imidazole, 2-methylimidazole, and chitosan. Examples of the inorganic base include tetramethylammonium hydroxide (TMAH), ammonia, potassium hydroxide, and sodium hydroxide. The pH adjusting agent may be used singly or in combination of two or more kinds thereof.

[Other Additives]

The polishing liquid of the present embodiment can contain additives other than the copolymer P, the dispersant, and the pH adjusting agent. Examples of such additives include a water-soluble polymer and a buffering agent for stabilizing pH. Examples of the water-soluble polymer include polysaccharides such as alginic acid, pectinic acid, carboxymethyl cellulose, agar, curdlan, or pullulan. The buffering agent may be added as a buffer solution (a solution containing a buffering agent). Examples of such a buffer solution include an acetate buffer solution and a phthalate buffer solution. These additives may be used singly or in combination of two or more kinds thereof.

(Liquid Medium)

The liquid medium in the polishing liquid of the present embodiment is not particularly limited, but is preferably water such as deionized water or ultrapure water. The content of the liquid medium may correspond to the remaining of the polishing liquid from which the contents of other constituent components are removed, and is not particularly limited.

(pH)

The lower limit of the pH of the polishing liquid of the present embodiment is preferably 4.0 or more, more preferably 4.5 or more, even more preferably 4.7 or more, and particularly preferably 4.9 or more, from the viewpoint of maintaining the stability of the polishing liquid and further improving the polishing rate for the insulating material. The upper limit of the pH of the polishing liquid of the present embodiment is preferably 6.5 or less, more preferably 6.0 or less, and even more preferably 5.5 or less, from the viewpoint of further improving flatness. From these viewpoints, the pH of the polishing liquid of the present embodiment is more preferably 4.0 to 6.5. The pH of the polishing liquid is the pH of the polishing liquid at 25° C.

The pH of the polishing liquid of the present embodiment can be measured by a pH meter (for example, Model No. D-51 manufactured by HORIBA, Ltd.). Specifically, for example, after performing 3-point calibration of the pH meter using a phthalate pH buffer solution (pH: 4.01), a neutral phosphate pH buffer solution (pH: 6.86), and a borate pH buffer solution (pH: 9.18) as standard buffer solutions, an electrode of the pH meter is placed in the polishing liquid, and the pH upon stabilization after an elapse of 2 minutes or longer is measured. At this time, both the liquid temperatures of the standard buffer solutions and the polishing liquid are set to 25° C.

(Others)

The polishing liquid of the present embodiment may be stored as a one-pack type polishing liquid containing at least the abrasive grains, the copolymer P, and the liquid medium. The one-pack type polishing liquid may be stored as a stock solution for a polishing liquid, in which the content of the liquid medium has been reduced, and may be used after being diluted with the liquid medium immediately before polishing or during polishing.

In the case of a one-pack type polishing liquid, as a method of supplying the polishing liquid onto a polishing platen, a method of supplying the polishing liquid by direct liquid conveyance; a method of conveying the stock solution for the polishing liquid and the liquid medium through separate tubings, merging them to mix, and then supplying; a method of mixing the stock solution for a polishing liquid and the liquid medium in advance and then supplying; or the like can be used.

<Polishing Liquid Set>

The polishing liquid of the present embodiment may be stored as a multi-pack type (for example, two-pack type) polishing liquid set (for example, a polishing liquid set for CMP) while the constituent components of the polishing liquid are divided into the slurry (first liquid) and the additive liquid (second liquid) so that the slurry and the additive liquid are mixed to obtain the polishing liquid. The slurry contains, for example, at least the abrasive grains and the liquid medium. The additive liquid contains, for example, at least the copolymer P and the liquid medium. The additive such as the copolymer P is preferably contained in the additive liquid among the slurry and the additive liquid. The constituent components of the polishing liquid may be stored as a polishing liquid set while being divided into three or more liquids.

In the polishing liquid set, the slurry and the additive liquid are mixed immediately before polishing or during polishing to prepare the polishing liquid. The multi-pack type polishing liquid set may be stored as a stock solution for slurry and a stock solution for additive liquid, in both of which the content of the liquid medium has been reduced, and may be used after being diluted with the liquid medium immediately before polishing or during polishing.

In the case of storage as a multi-pack type polishing liquid set including a slurry and an additive liquid, the polishing rate can be adjusted by arbitrarily changing the composition of each liquid. In the case of performing polishing using a polishing liquid set, as a method of supplying the polishing liquid onto the polishing platen, the following method is mentioned. For example, a method of conveying the slurry and the additive liquid through separate tubings, merging these tubings to mix, and then supplying; a method of conveying the stock solution for a slurry, the stock solution for an additive liquid, and the liquid medium through separate tubings, merging them to mix, and then supplying; a method of mixing the slurry and the additive liquid in advance and then supplying; a method of mixing the stock solution for a slurry, the stock solution for an additive liquid, and the liquid medium in advance and then supplying; or the like can be used. Furthermore, a method of respectively supplying the slurry and the additive liquid of the polishing liquid set onto the polishing platen can also be used. In this case, the polishing liquid obtained by mixing the slurry and the additive liquid on the polishing platen is used for polishing the surface to be polished.

<Polishing Method>

The polishing method of the present embodiment may include a polishing step of polishing a surface to be polished by using the one-pack type polishing liquid or may include a polishing step of polishing a surface to be polished by using a polishing liquid obtained by mixing the slurry and the additive liquid of the polishing liquid set. The polishing method of the present embodiment is, for example, a polishing method for a base substrate having a surface to be polished.

The polishing method of the present embodiment may be a polishing method for a base substrate having a surface to be polished containing an insulating material (such as silicon oxide) and a stopper material (such as silicon nitride or polysilicon). The base substrate may have, for example, an insulating member containing an insulating material and a stopper containing a stopper material. The polishing liquid of the present embodiment is preferably used for polishing a surface to be polished containing silicon oxide.

The polishing step may be, for example, a step of selectively polishing the insulating material with respect to the stopper material using the one-pack type polishing liquid or a polishing liquid obtained by mixing the slurry and the additive liquid of the polishing liquid set. The polishing method of the present embodiment may be a polishing method for a surface to be polished containing an insulating material and silicon nitride, in which the polishing method may include a step of selectively polishing the insulating material with respect to the silicon nitride using the one-pack type polishing liquid or a polishing liquid obtained by mixing the slurry and the additive liquid of the polishing liquid set. The polishing method of the present embodiment may be a polishing method for a surface to be polished containing an insulating material and polysilicon, in which the polishing method may include a step of selectively polishing the insulating material with respect to the polysilicon using the one-pack type polishing liquid or a polishing liquid obtained by mixing the slurry and the additive liquid of the polishing liquid set. The expression “selectively polishing a material A with respect to a material B” means that a polishing rate for the material A is higher than a polishing rate for the material B in the same polishing conditions. More specifically, for example, it means that the material A is polished at a polishing rate ratio of the polishing rate for the material A with respect to the polishing rate for the material B of preferably 15 or more (more preferably 20 or more).

In the polishing step, for example, while a surface to be polished of a base substrate having the surface to be polished is pressed on a polishing pad (polishing cloth) of a polishing platen, the polishing liquid is supplied between the surface to be polished and the polishing pad, and the base substrate and the polishing platen are relatively moved to polish the surface to be polished. In the polishing step, for example, at least a part of a material to be polished is removed by polishing.

As the base substrate which is an object to be polished, for example, a base substrate in which a material to be polished is formed on a substrate for semiconductor element production (for example, a semiconductor substrate in which an STI pattern, a gate pattern, a wiring pattern, or the like is formed) is exemplified. Examples of the material to be polished include an insulating material such as silicon oxide; and a stopper material such as silicon nitride or polysilicon. The material to be polished may be a single material or a plurality of materials. In the case in which the plurality of materials is exposed to the surface to be polished, these can be regarded as the materials to be polished. The material to be polished may be in the form of a film (film to be polished). The shape of the insulating member is not particularly limited, and for example, is a film shape (an insulating film) The shape of the stopper is not particularly limited, and for example, is a film shape (a stopper film: a silicon nitride film, a polysilicon film, or the like).

By polishing the material to be polished (for example, an insulating film such as a silicon oxide film) formed on the substrate using the polishing liquid of the present embodiment to remove an excess region, irregularities on the surface of the material to be polished are eliminated and thus a flat and smooth surface can be obtained over the entire polished surface.

In the present embodiment, it is possible to polish an insulating member of a base substrate which has a substrate having a concavo-convex pattern, a stopper disposed on the convex portion of the substrate, and the insulating member disposed on the substrate and the stopper so as to fill the concave portion of the concavo-convex pattern (a base substrate which has an insulating member (for example, a silicon oxide film containing silicon oxide on at least a surface), a stopper disposed at the lower layer of the insulating member, and a semiconductor substrate disposed below the stopper). In such a base substrate, since excessive polishing of the insulating member can be prevented by stopping the polishing when the stopper is exposed, the flatness of the insulating member after polishing can be improved. The stopper material constituting the stopper is a material having a polishing rate lower than that for the insulating material, and silicon nitride, polysilicon, or the like are preferred.

In the polishing method of the present embodiment, as a polishing apparatus, it is possible to use a common polishing apparatus which has a holder capable of holding a base substrate (semiconductor substrate or the like) having a surface to be polished and a polishing platen to which a polishing pad can be pasted. A motor or the like in which the number of rotations can be changed is attached to each of the holder and the polishing platen. As the polishing apparatus, for example, a polishing apparatus: Reflexion manufactured by Applied Materials, Inc. can be used.

As the polishing pad, common unwoven cloth, a foamed body, an unfoamed body, or the like can be used. As the material of the polishing pad, it is possible to use a resin such as polyurethane, an acrylic resin, polyester, an acrylic-ester copolymer, polytetrafluoroethylene, polypropylene, polyethylene, poly-4-methylpentene, cellulose, cellulose ester, polyamide (for example, Nylon (trade name) and aramid), polyimide, polyimidamide, a polysiloxane copolymer, an oxirane compound, a phenolic resin, polystyrene, polycarbonate, or an epoxy resin. As the material of the polishing pad, particularly, foamed polyurethane and unfoamed polyurethane are preferable from the viewpoint of being further excellent in polishing rate and flatness. It is preferable that the polishing pad is subjected to grooving so that the polishing liquid is pooled.

Polishing conditions are not particularly limited, but the rotation speed of the polishing platen is preferably 200 rpm (=rotations/min) or less such that the base substrate is not let out, and the polishing pressure to be applied to the base substrate (processing load) is preferably 100 kPa or less from the viewpoint of sufficiently suppressing the generation of polishing scratches. The polishing liquid is preferably continuously supplied to the polishing pad with a pump or the like during polishing. The amount supplied for this is not particularly limited, but it is preferable that the surface of the polishing pad is always covered with the polishing liquid.

The base substrate after the completion of polishing is preferably thoroughly washed in flowing water to remove the particles adhering to the base substrate. For the washing, dilute hydrofluoric acid or ammonia water may be used in addition to pure water, and a brush may be used to increase the washing efficiency. Furthermore, it is preferable that, after washing, the water droplets adhering to the base substrate are removed off using a spin dryer or the like, and then the base substrate is dried.

The polishing liquid, the polishing liquid set, and the polishing method of the present embodiment can be suitably used in formation of an STI. For the formation of the STI, the polishing rate ratio of the insulating material (silicon oxide or the like) with respect to the stopper material (silicon nitride, polysilicon or the like) is preferably 15 or more, and more preferably 20 or more. When the polishing rate ratio is less than 15, the magnitude of the polishing rate for the insulating material with respect to the polishing rate for the stopper material is small, and thus, it tends to be difficult to stop polishing at a predetermined position during formation of the STI. On the other hand, when the polishing rate ratio is 15 or more, it becomes easier to stop polishing, and thus, it is suitable for STI formation.

The polishing liquid, the polishing liquid set, and the polishing method of the present embodiment can also be used in polishing of a pre-metal insulating film. As the pre-metal insulating film, in addition to silicon oxide, for example, phosphorus-silicate glass, boron-phosphorus-silicate glass, silicon oxyfluoride, fluorinated amorphous carbon, and or like can be used.

The polishing liquid, the polishing liquid set, and the polishing method of the present embodiment can also be applied to materials other than the insulating material such as silicon oxide. Examples of such a material include high permittivity materials such as Hf-based, Ti-based, or Ta-based oxides; semiconductor materials such as silicon, amorphous silicon, SiC, SiGe, Ge, GaN, GaP, GaAs, or organic semiconductors; phase-change materials such as GeSbTe; inorganic conductive materials such as ITO; and polymer resin materials such as polyimide-based, polybenzooxazole-based, acrylic, epoxy-based, or phenol-based materials.

The polishing liquid, the polishing liquid set, and the polishing method of the present embodiment can also be applied not only to film-like objects to be polished, but also to various types of substrates made of glass, silicon, SiC, SiGe, Ge, GaN, GaP, GaAs, sapphire, plastics, or the like.

The polishing liquid, the polishing liquid set, and the polishing method of the present embodiment can be used not only for production of semiconductor elements, but also for production of image display devices such as TFTs or organic ELs; optical parts such as photomasks, lenses, prisms, optical fibers, or single crystal scintillators; optical elements such as optical switching elements or optical waveguides; light-emitting elements such as solid lasers or blue laser LEDs; and magnetic storage devices such as magnetic disks or magnetic heads.

### EXAMPLES

Hereinafter, the present invention will be described by means of Examples. However, the present invention is not limited to these Examples.

<Preparation of Polishing Liquid for CMP>

### Example 1

200 g of a stock solution for a slurry containing 5% by mass of ceria particles [cerium oxycarbonate-derived particles; ceria particles obtained by oxidizing cerium oxycarbonate], 0.05% by mass of ammonium dihydrogen phosphate (dispersant), and 94.95% by mass of water and 1700 g of a stock solution for an additive containing 0.25% by mass of styrene/acrylic acid copolymer (copolymer P) [ST/AA, styrene ratio: 50 mol %, Mw: 14000] and 99.75% by mass of water were mixed, and then 10% by mass of acetic acid aqueous solution was added so that the pH of the polishing liquid was adjusted to 5.1. Then, water was added so that the total amount became 2000 g, thereby a polishing liquid for CMP (2000 g) containing 0.5% by mass of ceria particles, 0.2% by mass of styrene/acrylic acid copolymer, and 0.005% by mass of ammonium dihydrogen phosphate was prepared.

### Example 2

A polishing liquid for CMP was prepared in the same manner as in Example 1, except that cerium carbonate-derived ceria particles [ceria particles obtained by oxidizing cerium carbonate] were used as the abrasive grains and an acrylic acid/methyl acrylate copolymer (AA/AM, Mw: 8000) was used as the dispersant.

### Example 3

A polishing liquid for CMP was prepared in the same manner as in Example 1, except that a styrene/acrylic acid copolymer [styrene ratio: 30 mol %, Mw: 16000] was used as the copolymer P.

A polishing liquid for CMP was prepared in the same manner as in Example 1, except that a styrene/acrylic acid copolymer [styrene ratio: 30 mol %, Mw: 8000] was used as the copolymer P.

### Example 5

A polishing liquid for CMP was prepared in the same manner as in Example 3, except that cerium carbonate-derived ceria particles were used as the abrasive grains.

### Example 6

A polishing liquid for CMP was prepared in the same manner as in Example 1, except that a styrene/acrylic acid copolymer [styrene ratio: 20 mol %, Mw: 18000] was used as the copolymer P.

### Example 7

A polishing liquid for CMP was prepared in the same manner as in Example 1, except that a styrene/acrylic acid copolymer [styrene ratio: 15 mol %, Mw: 17000] was used as the copolymer P.

### Example 8

A polishing liquid for CMP was prepared in the same manner as in Example 1, except that a styrene/maleic acid copolymer [ST/MA, styrene ratio: 50 mol %, Mw: 6000] was used as the copolymer P.

### Comparative Example 1

A polishing liquid for CMP was prepared in the same manner as in Example 1, except that the copolymer P of Example 1 was changed to a styrene/acrylic acid copolymer [styrene ratio: 10 mol %, Mw: 15000].

### Comparative Example 2

A polishing liquid for CMP was prepared in the same manner as in Example 5, except that the copolymer P of Example 5 was changed to a styrene/acrylic acid copolymer [styrene ratio: 10 mol %, Mw: 15000].

### Comparative Example 3

A polishing liquid for CMP was prepared in the same manner as in Example 2, except that the copolymer P of Example 2 was changed to a styrene/acrylic acid copolymer [styrene ratio: 10 mol %, Mw: 15000].

### Comparative Example 4

A polishing liquid for CMP was prepared in the same manner as in Example 1, except that the copolymer P of Example 1 was changed to polyacrylic acid [PAA, styrene ratio: 0 mol %, Mw: 2000].

### Comparative Example 5

A polishing liquid for CMP was prepared in the same manner as in Example 5, except that the copolymer P of Example 5 was changed to polyacrylic acid [styrene ratio: 0 mol %, Mw: 2000].

### Comparative Example 6

A polishing liquid for CMP was prepared in the same manner as in Example 2, except that the copolymer P of Example 2 was changed to polyacrylic acid [styrene ratio: 0 mol %, Mw: 2000].

<Evaluation of Polishing Liquid Characteristics>

The pH of the polishing liquid for CMP obtained above, the average particle diameter of the abrasive grains in the polishing liquid for CMP, and the zeta potential (surface potential) of the abrasive grains were evaluated as follows.

(pH)

Measurement temperature: 25±5° C.

Measurement apparatus: Model No. D-51 manufactured by HORIBA, Ltd.

Measurement method: After performing 3-point calibration using a standard buffer solution (phthalate pH buffer solution, pH: 4.01 (25° C.); neutral phosphate pH buffer solution, pH: 6.86 (25° C.); borate pH buffer solution, pH: 9.18 (25° C.)), an electrode was placed in the polishing liquid for CMP, and the pH upon stabilization after an elapse of 2 minutes or longer was measured by the measurement apparatus.

(Average Particle Diameter of Abrasive Grains)

An appropriate amount of the polishing liquid for CMP was introduced into Microtrac MT3300EXII (trade name) manufactured by MicrotracBEL Corp., and the average particle diameter of the abrasive grains was measured. The displayed average particle diameter value was obtained as the average particle diameter (average secondary particle diameter, D50). The average particle diameter was 150 nm.

(Zeta Potential of Abrasive Grains)

An appropriate amount of the polishing liquid for CMP was introduced and set into a dense cell unit of DelsaNano C (device name) manufactured by Beckman Coulter, Inc. The measurement was performed at 25° C. twice, and the average value of the displayed zeta potential was obtained as the zeta potential. The zeta potential was −50 mV.

<CMP Evaluation>

The substrate to be polished was polished using the polishing liquid for CMP under the following polishing conditions. The polishing of the pattern wafer was performed using the polishing liquids for CMP of Examples 1 to 4 and 8 and Comparative Examples 1 and 2.

(CMP Polishing Conditions)
Polishing apparatus: Reflexion LK (manufactured by Applied Materials, Inc.)
Flow rate of polishing liquid for CMP: 250 ml/min
Substrate to be polished: Blanket wafer and pattern wafer described below
Polishing pad: Foamed polyurethane resin having closed pores (manufactured by Rohm and Haas Japan K.K., Product No.: IC1010)
Polishing pressure: 3.0 psi
Number of rotations of substrate and polishing platen: Substrate/polishing platen=93/87 rpm
Polishing time: A blanket wafer was polished for 1 minute. The polishing time of a pattern wafer is shown in the table.
Drying of wafer: After a CMP treatment, drying was performed by a spin dryer.

[Blanket Wafer]

As a blanket wafer (BTW) with no patterns formed, a base substrate having a silicon oxide film with a thickness of 1 μm formed on a silicon substrate by a plasma CVD method, a base substrate having a silicon nitride film with a thickness of 0.2 μm formed on a silicon substrate by a CVD method, and a base substrate having a polysilicon film with a thickness of 0.15 μm formed on a silicon substrate by a CVD method were used.

[Pattern Wafer]

As a pattern wafer (PTW) with a simulated pattern formed, 764 wafer (trade name, diameter: 300 mm) manufactured by SEMATECH was used. This pattern wafer was a wafer obtained by stacking a silicon nitride film as a stopper on a silicon substrate, then forming a trench in an exposure and developing step, and then stacking a silicon oxide film (SiO₂ film) as an insulating film on the silicon substrate and the stopper so as to fill the stopper and the trench. The silicon oxide film was formed by a HDP (High Density Plasma) method.

The pattern wafer had a portion with a line (L) as a convex portion/a space (S) as a concave portion of 1000 μm pitch and a convex pattern density of 50% (L/S=500/500 μm); a portion with an L/S of 200 μm pitch and a convex pattern density of 50% (L/S=100/100 μm); a portion with an L/S having 100 μm pitch and a convex pattern density of 50% (L/S=50/50 μm); and a portion with an L/S having 100 μm pitch and a convex pattern density of 20% (L/S=20/80 μm).

The L/S is a simulated pattern and a pattern in which an Active portion as a convex portion masked by the silicon nitride film and a Trench portion as a concave portion with a groove formed are alternately arranged. For example, “an L/S of 100 μm pitch” means that the total of the width of the Active portion (line portion) and the Trench portion (space portion) is 100 μm. Furthermore, for example, “an L/S of 100 μm pitch and a convex pattern density of 50%” means a pattern in which a convex portion having a width of 50 μm and a concave portion having a width of 50 μm are alternately arranged.

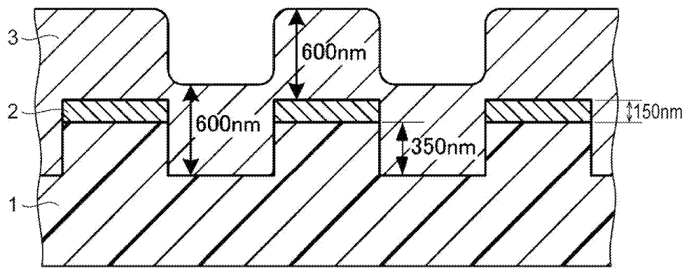

In the pattern wafer, the film thickness of the silicon oxide film was 600 nm on each of the silicon substrate at the concave portion and the silicon nitride film on the convex portion. Specifically, as illustrated in FIG. 1, the film thickness of a silicon nitride film 2 on a silicon substrate 1 was 150 nm, the film thickness of a silicon oxide film 3 on the convex portion was 600 nm, the film thickness of the silicon oxide film 3 in the concave portion was 600 nm, and the depth of the concave portion of the silicon oxide film 3 was 500 nm (350 nm of the trench depth+150 nm of the film thickness of the silicon nitride film).

In evaluation of the pattern wafer, a known polishing liquid for CMP capable of obtaining self-stopping property (property for reducing the polishing rate in accordance with a decrease in the remaining step height in the simulated pattern) was used to polish the wafer, and a wafer in which the remaining step height was about 200 nm was used. Specifically, a wafer, which was polished until the film thickness of the silicon oxide film on the convex portion with an L/S of 100 μm pitch and a convex pattern density of 50% reached about 300 nm using a polishing liquid in which HS-8005-D4 (trade name) manufactured by Hitachi Chemical Company, Ltd., HS-7303GP (trade name) manufactured by Hitachi Chemical Company, Ltd., and water were blended in a ratio of 2:1.2:6.8, was used.

(Evaluation of Blanket Wafer (BTW Polishing Characteristics))

The polishing rate for each film to be polished (the silicon oxide film, the silicon nitride film, and the polysilicon film) of the blanket wafer polished and washed under the above conditions was determined by the equation below. The difference in film thickness of each film to be polished before and after polishing was determined using a light interference type film thickness measuring apparatus (manufactured by Filmetrics Japan, Inc., trade name: F80). Furthermore, the polishing selection ratio of the silicon oxide with respect to the silicon nitride and the polishing selection ratio of the silicon oxide with respect to the polysilicon were calculated.

(Polishing rate)=(Difference in film thickness [nm] of each film to be polished before and after polishing)/(Polishing time [min])

(Evaluation of Pattern Wafer (PTW Polishing Characteristics))

The polishing rate for the pattern wafer (PTWRR), the remaining step height amount (dishing amount), and the silicon nitride loss amount (stopper loss amount) were calculated. The remaining step height amount and the silicon nitride loss amount were calculated at a time when the stopper was exposed (the left side of the polishing time described in the table) and at a time when polishing was performed at the PTWRR for a time corresponding to about 100 nm after the stopper was exposed (the right side of the polishing time described in the table; the total polishing time from the beginning)

The polishing rate for the pattern wafer (PTWRR) was determined using the film thickness of the silicon oxide film on the convex portion before polishing in a portion with L/S=50/50 μm and the polishing time until the stopper on the convex portion was exposed, by the equation below.

(Pattern wafer polishing rate: PTWRR)=(Film thickness [nm] of the silicon oxide film on the convex portion before polishing)/(Polishing time [min] until the stopper on the convex portion is exposed)

In the pattern wafer polished and washed under the above conditions, a portion with an L/S of 1000 μm pitch and a convex pattern density of 50% (L/S=500/500 μm), a portion with an L/S of 200 μm pitch and a convex pattern density of 50% (L/S=100/100 μm), a portion with an L/S of 100 μm pitch and a convex pattern density of 50% (L/S=50/50 μm), and a portion with an L/S of 100 μm pitch and a convex pattern density of 20% (L/S=20/80 μm) were respectively scanned by a contact type step meter (trade name: P-16 manufactured by KLA-Tencor Japan), and a height difference between the convex portion and the concave portion was measured, thereby the remaining step height amount was obtained.

The silicon nitride loss amount was determined from a difference between the initial film thickness of the stopper on the convex portion and the remaining film thickness of the stopper on the convex portion after polishing, by the equation below. The film thicknesses of each film to be polished before and after polishing were determined using a light interference type film thickness measuring apparatus (trade name: Nanospec AFT-5100 manufactured by Nanometrics Incorporated).

(Silicon nitride loss amount [nm])=(Initial film thickness of the stopper on the convex portion: 150 [nm])−(Remaining film thickness [nm] of the stopper on the convex portion after polishing)

The respective measurement results obtained in Examples and Comparative Examples are shown in Tables 1 and 2.

TABLE 1

| | | | Example | | | | | | | | | | | | | | | |
|---|---|---|---|---|---|---|---|---|---|---|---|---|---|---|---|---|---|---|
| Item | | | 1 | | 2 | | 3 | | 4 | | 5 | | 6 | | 7 | | 8 | |
| Abrasive | Cerium source | | Cerium | | Cerium | | Cerium | | Cerium | | Cerium | | Cerium | | Cerium | | Cerium | |
| grains | | | oxy- | | car- | | oxy- | | oxy- | | car- | | oxy- | | oxy- | | oxy- | |
| | | | car- | | bonate | | car- | | car- | | bonate | | car- | | car- | | car- | |
| | | | bonate | | | | bonate | | bonate | | | | bonate | | bonate | | bonate | |
| | Type | | Ceria particles | | | | | | | | | | | | | | | |
| | Content (% by mass) | | 0.5 | | | | | | | | | | | | | | | |
| Additive | Copolymer | Type | ST/AA | | ST/AA | | ST/AA | | ST/AA | | ST/AA | | ST/AA | | ST/AA | | ST/MA | |
| | P | Ratio of | 50 | | 50 | | 30 | | 30 | | 30 | | 20 | | 15 | | 50 | |
| | | styrene | | | | | | | | | | | | | | | | |
| | | compound | | | | | | | | | | | | | | | | |
| | | (mol %) | | | | | | | | | | | | | | | | |
| | | Weight | 14000 | | 14000 | | 16000 | | 8000 | | 16000 | | 18000 | | 17000 | | 6000 | |
| | | average | | | | | | | | | | | | | | | | |
| | | molecular | | | | | | | | | | | | | | | | |
| | | weight | | | | | | | | | | | | | | | | |
| | | Mw | | | | | | | | | | | | | | | | |
| | | Content | 0.2 | | | | | | | | | | | | | | | |
| | | (% by mass) | | | | | | | | | | | | | | | | |
| | Dispersant | Type | Ammo- | | AA/AM | | Ammo- | | Ammo- | | Ammo- | | Ammo- | | Ammo- | | Ammo- | |
| | | | nium | | | | nium | | nium | | nium | | nium | | nium | | nium | |
| | | | dihy- | | | | dihy- | | dihy- | | dihy- | | dihy- | | dihy- | | dihy- | |
| | | | drogen | | | | drogen | | drogen | | drogen | | drogen | | drogen | | drogen | |
| | | | phos- | | | | phos- | | phos- | | phos- | | phos- | | phos- | | phos- | |
| | | | phate | | | | phate | | phate | | phate | | phate | | phate | | phate | |
| | | Content | 0.005 | | | | | | | | | | | | | | | |
| | | (% by mass) | | | | | | | | | | | | | | | | |
| | pH | Type | Acetic acid | | | | | | | | | | | | | | | |
| | adjusting | | | | | | | | | | | | | | | | | |
| | agent | | | | | | | | | | | | | | | | | |
| Polishing | PH | | 5.1 | | | | | | | | | | | | | | | |
| liquid | Average particle | | 150 | | | | | | | | | | | | | | | |
| character- | diameter D50 (nm) | | | | | | | | | | | | | | | | | |
| istics | Zeta potential (mV) | | −50 | | | | | | | | | | | | | | | |
| BTW | Polishing | Silicon oxide | 91.0 | | 75.0 | | 90.0 | | 85.0 | | 105.0 | | 78.0 | | 74.0 | | 87.0 | |
| polishing | rate | film: Ox | | | | | | | | | | | | | | | | |
| character- | | (nm/min) | | | | | | | | | | | | | | | | |
| istics | | Silicon nitride | 0.6 | | 2.7 | | 3.1 | | 3.6 | | 4.2 | | 4.5 | | 5.0 | | 2.0 | |
| | | film: SiN | | | | | | | | | | | | | | | | |
| | | (nm/min) | | | | | | | | | | | | | | | | |
| | | Polysilicon | 4.0 | | 3.5 | | 4.1 | | 4.2 | | 5.1 | | 4.5 | | 5.0 | | 3.8 | |
| | | film: | | | | | | | | | | | | | | | | |
| | | pSi (nm/min) | | | | | | | | | | | | | | | | |
| | Polishing | Ox/SiN | 152.0 | | 28.0 | | 29.0 | | 24.0 | | 25.0 | | 17.0 | | 15.0 | | 44.0 | |
| | selection | Ox/pSi | 23.0 | | 21.0 | | 22.0 | | 20.0 | | 21.0 | | 17.0 | | 15.0 | | 23.0 | |
| | ratio | | | | | | | | | | | | | | | | | |
| PTW | Polishing rate (nm/min) | | 189 | | 150 | | 300 | | 277 | | — | | — | | — | | 203 | |
| polishing | Polishing time (s) | | 95 | 125 | 120 | 150 | 60 | 80 | 65 | 85 | — | — | — | — | — | — | 90 | 110 |
| character- | L/S = | Remaining | 4.6 | 0.0 | 6.0 | 4.0 | 8.4 | 0.0 | 9.9 | 4.3 | — | — | — | — | — | — | 0.0 | 5.0 |
| istics | 500/500 μm | step height | | | | | | | | | | | | | | | | |
| | | amount | | | | | | | | | | | | | | | | |
| | | (nm) | | | | | | | | | | | | | | | | |
| | | SiN loss | 0.0 | 0.0 | 0.8 | 1.3 | 0.0 | 0.6 | 0.0 | 0.5 | — | — | — | — | — | — | 1.5 | 1.8 |
| | | amount | | | | | | | | | | | | | | | | |
| | | (nm) | | | | | | | | | | | | | | | | |
| | L/S = | Remaining | 0.0 | 0.0 | 0.0 | 0.0 | 0.0 | 0.0 | 0.0 | 0.0 | — | — | — | — | — | — | 0.9 | 0.0 |
| | 100/100 μm | step height | | | | | | | | | | | | | | | | |
| | | amount | | | | | | | | | | | | | | | | |
| | | (nm) | | | | | | | | | | | | | | | | |
| | | SiN loss | 0.0 | 0.0 | 0.0 | 0.0 | 0.0 | 0.0 | 0.0 | 0.0 | — | — | — | — | — | — | 0.4 | 0.8 |
| | | amount | | | | | | | | | | | | | | | | |
| | | (nm) | | | | | | | | | | | | | | | | |
| | L/S = | Remaining | 0.0 | 0.0 | 0.0 | 0.0 | 0.0 | 0.0 | 0.0 | 0.0 | — | — | — | — | — | — | 2.8 | 2.8 |
| | 50/50 μm | step height | | | | | | | | | | | | | | | | |
| | | amount | | | | | | | | | | | | | | | | |
| | | (nm) | | | | | | | | | | | | | | | | |
| | | SiN loss | 0.0 | 0.0 | 0.0 | 0.9 | 0.0 | 0.1 | 0.0 | 0.1 | — | — | — | — | — | — | 0.5 | 0.8 |
| | | amount | | | | | | | | | | | | | | | | |
| | | (nm) | | | | | | | | | | | | | | | | |
| | L/S = | Remaining | 6.0 | 8.2 | 0.0 | 13.0 | 0.0 | 6.0 | 0.0 | 8.6 | — | — | — | — | — | — | 10.0 | 11.0 |
| | 20/80 μm | step height | | | | | | | | | | | | | | | | |
| | | amount | | | | | | | | | | | | | | | | |
| | | (nm) | | | | | | | | | | | | | | | | |
| | | SiN loss | 3.9 | 5.5 | 8.0 | 9.5 | 0.0 | 1.1 | 0.2 | 1.8 | — | — | — | — | — | — | 2.1 | 3.5 |
| | | amount | | | | | | | | | | | | | | | | |
| | | (nm) | | | | | | | | | | | | | | | | |

TABLE 2

| | | | ComparativeExample | | | | | | | | | | | |
|---|---|---|---|---|---|---|---|---|---|---|---|---|---|---|
| Item | | | 1 | | 2 | | 3 | | 4 | | 5 | | 6 | |
| Abrasive | Cerium source | | Cerium | | Cerium | | Cerium | | Cerium | | Cerium | | Cerium | |
| grains | | | oxy- | | car- | | car- | | oxy- | | car- | | car- | |
| | | | car- | | bonate | | bonate | | car- | | bonate | | bonate | |
| | | | bonate | | | | | | bonate | | | | | |
| | Type | | Ceria particles | | | | | | | | | | | |
| | Content (% by mass) | | 0.5 | | | | | | | | | | | |
| Additive | Polymer | Type | ST/AA | | ST/AA | | ST/AA | | PAA | | PAA | | PAA | |
| | | Ratio of | 10 | | 10 | | 10 | | 0 | | 0 | | 0 | |
| | | styrene | | | | | | | | | | | | |
| | | compound | | | | | | | | | | | | |
| | | (mol %) | | | | | | | | | | | | |
| | | Weight | 15000 | | 15000 | | 15000 | | 2000 | | 2000 | | 2000 | |
| | | average | | | | | | | | | | | | |
| | | molecular | | | | | | | | | | | | |
| | | weight | | | | | | | | | | | | |
| | | Mw | | | | | | | | | | | | |
| | | Content | 0.2 | | | | | | | | | | | |
| | | (% by mass) | | | | | | | | | | | | |
| | Dispersant | Type | Ammo- | | Ammo- | | AA/AM | | Ammo- | | Ammo- | | AA/AM | |
| | | | nium | | nium | | | | nium | | nium | | | |
| | | | dihy- | | dihy- | | | | dihy- | | dihy- | | | |
| | | | drogen | | drogen | | | | drogen | | drogen | | | |
| | | | phos- | | phos- | | | | phos- | | phos- | | | |
| | | | phate | | phate | | | | phate | | phate | | | |
| | | Content | 0.005 | | | | | | | | | | | |
| | | (% by mass) | | | | | | | | | | | | |
| | pH | Type | Acetic acid | | | | | | | | | | | |
| | adjusting | | | | | | | | | | | | | |
| | agent | | | | | | | | | | | | | |
| Polishing | PH | | 5.1 | | | | | | | | | | | |
| liquid | Average particle | | 150 | | | | | | | | | | | |
| character- | diameter D50 (nm) | | | | | | | | | | | | | |
| istics | Zeta potential (mV) | | −50 | | | | | | | | | | | |
| BTW | Polishing | Silicon oxide | 70.0 | | 90.0 | | 36.0 | | 60.2 | | 83.0 | | 32.0 | |
| polishing | rate | film: Ox | | | | | | | | | | | | |
| character- | | (nm/min) | | | | | | | | | | | | |
| istics | | Silicon nitride | 7.8 | | 8.7 | | 10.0 | | 8.6 | | 8.8 | | 11.0 | |
| | | film: SiN | | | | | | | | | | | | |
| | | (nm/min) | | | | | | | | | | | | |
| | | Polysilicon | 18.0 | | 20.0 | | 20.0 | | 64.0 | | 65.0 | | 68.0 | |
| | | film: | | | | | | | | | | | | |
| | | pSi (nm/min) | | | | | | | | | | | | |
| | Polishing | Ox/SiN | 9.0 | | 10.0 | | 3.6 | | 7.0 | | 9.0 | | 3.0 | |
| | selection | Ox/pSi | 4.0 | | 5.0 | | 1.8 | | 1.0 | | 1.0 | | 0.5 | |
| | ratio | | | | | | | | | | | | | |
| PTW | Polishing rate (nm/min) | | 150 | | 240 | | — | | — | | — | | — | |
| polishing | Polishing time (s) | | 120 | 140 | 75 | 95 | — | — | — | — | — | — | — | — |
| character- | L/S = | Remaining | 33.7 | 45.8 | 37.8 | 48.3 | — | — | — | — | — | — | — | — |
| istics | 500/500 μm | step height | | | | | | | | | | | | |
| | | amount | | | | | | | | | | | | |
| | | (nm) | | | | | | | | | | | | |
| | | SiN loss | 0.0 | 7.2 | 0.4 | 7.1 | — | — | — | — | — | — | — | — |
| | | amount | | | | | | | | | | | | |
| | | (nm) | | | | | | | | | | | | |
| | L/S = | Remaining | 16.0 | 18.8 | 24.5 | 24.8 | — | — | — | — | — | — | — | — |
| | 100/100 μm | step height | | | | | | | | | | | | |
| | | amount | | | | | | | | | | | | |
| | | (nm) | | | | | | | | | | | | |
| | | SiN loss | 0.0 | 4.7 | 0.0 | 3.6 | — | — | — | — | — | — | — | — |
| | | amount | | | | | | | | | | | | |
| | | (nm) | | | | | | | | | | | | |
| | L/S = | Remaining | 14.0 | 17.1 | 15.2 | 21.5 | — | — | — | — | — | — | — | — |
| | 50/50 μm | step height | | | | | | | | | | | | |
| | | amount | | | | | | | | | | | | |
| | | (nm) | | | | | | | | | | | | |
| | | SiN loss | 0.0 | 7.2 | 0.0 | 8.2 | — | — | — | — | — | — | — | — |
| | | amount | | | | | | | | | | | | |
| | | (nm) | | | | | | | | | | | | |
| | L/S = | Remaining | 18.6 | 22.1 | 20.6 | 29.5 | — | — | — | — | — | — | — | — |
| | 20/80 μm | step height | | | | | | | | | | | | |
| | | amount | | | | | | | | | | | | |
| | | (nm) | | | | | | | | | | | | |
| | | SiN loss | 0.0 | 10.3 | 1.7 | 16.2 | — | — | — | — | — | — | — | — |
| | | amount | | | | | | | | | | | | |
| | | (nm) | | | | | | | | | | | | |

According to Tables 1 and 2, in Examples, the results showing that the polishing selectivity of the insulating material with respect to the stopper material can be improved as compared with Comparative Examples were obtained. Furthermore, in Examples, the results showing that the remaining step height and the silicon nitride loss amount were sufficiently suppressed as compared with Comparative Examples were obtained.

### REFERENCE SIGNS LIST

1: silicon substrate, 2: silicon nitride film, 3: silicon oxide film.

1. A polishing liquid comprising abrasive grains, a copolymer, and a liquid medium, wherein
the copolymer has a structure unit derived from at least one styrene compound selected from the group consisting of styrene and a styrene derivative and a structure unit derived from at least one selected from the group consisting of acrylic acid and maleic acid, and
a ratio of the structure unit derived from the styrene compound in the copolymer is 15 mol % or more.

2. The polishing liquid according to claim 1, wherein a zeta potential of the abrasive grains is negative.

3. The polishing liquid according to claim 1, wherein the ratio of the structure unit derived from the styrene compound is 15 to 60 mol %.

4. The polishing liquid according to claim 1, wherein the copolymer has a structure unit derived from styrene.

5. The polishing liquid according to claim 1, wherein the copolymer has a structure unit derived from acrylic acid.

6. The polishing liquid according to claim 1, wherein the copolymer has a structure unit derived from maleic acid.

7. The polishing liquid according to claim 1, wherein a degree of solubility of the styrene compound with respect to water at 25° C. is 0.1 g/100 ml or less.

8. The polishing liquid according to claim 1, wherein a weight average molecular weight of the copolymer is 20000 or less.

9. The polishing liquid according to claim 1, wherein a content of the copolymer is 0.05 to 2.0% by mass.

10. The polishing liquid according to claim 1, wherein the abrasive grains contain at least one selected from the group consisting of ceria, silica, alumina, zirconia, and yttria.

11. The polishing liquid according to claim 1, wherein the abrasive grains contain cerium oxycarbonate-derived ceria.

12. The polishing liquid according to claim 1, further comprising at least one selected from the group consisting of a phosphate and a polymer having a structure unit derived from acrylic acid.

13. (canceled)

14. A polishing liquid set comprising constituent components of the polishing liquid according to claim 1 stored while being divided into a first liquid and a second liquid, the first liquid containing the abrasive grains and a liquid medium, the second liquid containing the copolymer and a liquid medium.

15. A polishing method comprising a step of polishing a surface to be polished by using the polishing liquid according to claim 1.

16. A polishing method for a surface to be polished containing an insulating material and silicon nitride, the polishing method comprising:
a step of selectively polishing the insulating material with respect to the silicon nitride by using the polishing liquid according to claim 1.

17. A polishing method for a surface to be polished containing an insulating material and polysilicon, the polishing method comprising:
a step of selectively polishing the insulating material with respect to the polysilicon by using the polishing liquid according to claim 1.

18. The polishing liquid according to claim 1, further comprising a phosphate.

19. The polishing liquid according to claim 1, wherein a content of the abrasive grains is 0.05 to 1.0% by mass, and a content of the copolymer is 0.07% by mass or more.

20. A polishing method comprising a step of polishing a surface to be polished by using a polishing liquid obtained by mixing the first liquid and the second liquid of the polishing liquid set according to claim 14.

21. A polishing method for a surface to be polished containing an insulating material and silicon nitride, the polishing method comprising:
a step of selectively polishing the insulating material with respect to the silicon nitride by using a polishing liquid obtained by mixing the first liquid and the second liquid of the polishing liquid set according to claim 14.

22. A polishing method for a surface to be polished containing an insulating material and polysilicon, the polishing method comprising:
a step of selectively polishing the insulating material with respect to the polysilicon by using a polishing liquid obtained by mixing the first liquid and the second liquid of the polishing liquid set according to claim 14.

23. The polishing method according to claim 15, wherein the surface to be polished contains silicon oxide.

24. The polishing method according to claim 20, wherein the surface to be polished contains silicon oxide.
